(19) United States
(12) Patent Application Publication
(10) Pub. No.: US 2025/0030261 A1
(43) Pub. Date: Jan. 23, 2025

(54) METHOD, DEVICE, COMPUTER APPARATUS, AND READABLE STORAGE MEDIUM FOR CONTROLLING BATTERY

(71) Applicant: SHENZHEN ENEXEED NEW ENERGY CO., LTD., Shenzhen (CN)

(72) Inventors: Yuqiang XIA, Shenzhen (CN); Liangxin YANG, Shenzhen (CN)

(73) Assignee: SHENZHEN ENEXEED NEW ENERGY CO., LTD., Shenzhen (CN)

(21) Appl. No.: 18/511,281

(22) Filed: Nov. 16, 2023

(30) Foreign Application Priority Data
Jul. 17, 2023 (CN) 202310873784.8

(51) Int. Cl. H02J 7/00; G01R 31/3835; H01M 10/44; H01M 10/48; G01K 3/00

(52) U.S. Cl. CPC H02J 7/007182; G01R 31/3835; H01M 10/443; H01M 10/486; H02J 7/0047; H02J 7/007194; G01K 3/005

(57) ABSTRACT

The present disclosure provides a method, device, computer apparatus, and readable storage medium for controlling a battery, belonging to the field of processing technology. The method includes obtaining a first initial adjustment factor and a second initial adjustment factor based on the current application scenario of the battery, and obtaining a target output voltage of the battery; monitoring an actual output voltage of the battery in real time; and adjusting, if the difference between the actual output voltage and the target output voltage is greater than a preset threshold, the first initial adjustment factor and/or the second initial adjustment factor based on the target output voltage and the actual output voltage, so as to make the difference between the actual output voltage and the target output voltage less than or equal to the preset threshold.

### CROSS-REFERENCES TO RELATED APPLICATIONS

The present disclosure claims the priority to the Chinese patent application with the filing No. 2023108737848, entitled “Method, Device, Computer Apparatus, and Readable Storage Medium for Controlling Battery” filed with the Chinese Patent Office on Jul. 17, 2023, the entire content of which is incorporated herein by reference.

### TECHNICAL FIELD

The present disclosure relates to the field of battery charging control technology, and in particular to a method, device, computer apparatus, and readable storage medium for controlling a battery.

### BACKGROUND ART

Lithium-ion batteries have the advantages of high specific energy, small size, and long cycle life, so lithium-ion batteries are widely used in various fields, such as transportation power supply, electric-power storage power supply, mobile communication power supply, new energy storage power supply, and aerospace power supply. In the field of lithium-ion batteries, lithium-ion batteries are highly sensitive to charging voltage and temperature. Improper control and management for lithium-ion batteries can lead to incidents such as combustion or explosions. Therefore, how to control the charging and discharging of batteries is an important issue.

In related technologies, it is generally accomplished through battery detection and control circuits that monitor the charging voltage applied to the battery and the output voltage of the battery, which control DC-DC step-down voltage-regulated discharge circuits and battery charging control circuits to put the battery into a charging state or turn off the charging state. Based on the preset battery voltage at low quantity of electricity, the preset battery threshold hysteresis voltage, and preset battery discharge cutoff voltage, voltage-stabilization discharging of the battery or stopping discharging is controlled by the DC-DC step-down voltage-regulated discharge circuits. Additionally, it is also possible to monitor the temperature of the battery through battery detection and control circuits and control the battery charging control circuit to either limit or resume battery charging.

However, when applying battery control based on related technologies, there are issues such as poor battery application flexibility and shortened usage duration of the battery.

### SUMMARY

The objective of the present disclosure is to provide a method, device, computer equipment, and readable storage medium for controlling a battery, which can achieve the effect of improving the flexibility of battery applications and extending the usage duration of the battery.

The embodiments of the present disclosure are implemented as follows.

In the first aspect, the embodiments of the present disclosure provide a method for controlling the battery, comprising:
obtaining a first initial adjustment factor and a second initial adjustment factor based on the current application scenario of the battery, and obtaining a target output voltage of the battery;
monitoring an actual output voltage of the battery in real time; and
adjusting, if the difference between the actual output voltage and the target output voltage is greater than a preset threshold, the first initial adjustment factor and/or the second initial adjustment factor based on the target output voltage and the actual output voltage, so as to make the difference between the actual output voltage and the target output voltage less than or equal to the preset threshold.

As an optional embodiment, the step of adjusting the first initial adjustment factor and/or the second initial adjustment factor based on the target output voltage and the actual output voltage comprises:
determining a sum of the actual output voltage and the first initial adjustment factor;
determining a product of the sum and the second initial adjustment factor; and
adjusting the first initial adjustment factor and/or the second initial adjustment factor based on the difference between the product and the target output voltage.

As an optional embodiment, the method for controlling the battery further comprises: monitoring a temperature of the battery in real time; and
stopping discharging, if the temperature of the battery is greater than or equal to a first preset temperature threshold, and re-controlling the battery to discharge when the temperature of the battery is less than or equal to a second preset temperature threshold, wherein the second preset threshold is less than the first preset threshold.

As an optional embodiment, the method for controlling the battery further comprises:
stopping discharging, if the actual output voltage of the battery is less than or equal to the preset discharge cutoff voltage.

As an optional embodiment, the method for controlling the battery further comprises:
monitoring a temperature of the battery in real time; and
charging the battery first in trickle charging mode, if the temperature of the battery is less than or equal to a third preset temperature threshold, and then charging the battery in normal charging mode when the temperature of the battery is greater than or equal to a fourth preset temperature threshold, wherein the fourth preset temperature threshold is greater than the third preset temperature threshold.

As an optional embodiment, the method for controlling the battery further comprises:
stopping charging, if the temperature of the battery is greater than or equal to a fifth preset temperature threshold, and recharging the battery when the temperature of the battery is less than or equal to a sixth preset temperature threshold, wherein the sixth preset temperature threshold is less than the fifth preset temperature threshold.

As an optional embodiment, the method for controlling the battery further comprises:
charging the battery first in trickle charging mode, if the actual output voltage of the battery is less than or equal to a first preset voltage, and charging the battery in constant-voltage and constant-current mode when the actual output voltage of the battery is greater than a second preset voltage.

In a second aspect, the embodiments of the present disclosure provide a device for controlling the battery, the device for controlling the battery comprises:
an obtaining module, configured for obtaining a first initial adjustment factor and a second initial adjustment factor based on the current application scenario of the battery, and obtaining a target output voltage of the battery;
a monitoring module, configured for monitoring an actual output voltage of the battery in real time; and
an adjusting module, configured for adjusting, if the difference between the actual output voltage and the target output voltage is greater than a preset threshold, the first initial adjustment factor and/or the second initial adjustment factor based on the target output voltage and the actual output voltage, so as to make the difference between the actual output voltage and the target output voltage less than or equal to the preset threshold.

In the third aspect, the embodiments of the present disclosure provide a computer apparatus. The computer apparatus comprises a memory, a processor, and a computer program stored in the memory that can be executed on the processor. When the processor executes the computer program, the method for controlling the battery as described in the first aspect is implemented.

In the fourth aspect, the embodiments of the present disclosure provide a computer-readable storage medium. The computer-readable storage medium stores a computer program, and when the computer program is executed by a processor, the method for controlling the battery as described in the first aspect is implemented.

The embodiments of the present disclosure comprise the following beneficial effects.

The embodiments of the present disclosure provide a method for controlling the battery. By determining the current application scenario of the battery, determining the target output voltage corresponding to the battery, obtaining the first initial adjustment factor and the second initial adjustment factor stored in the processor, obtaining the actual output voltage of the battery in real time, and adjusting the first initial adjustment factor and/or the second initial adjustment factor in real-time based on the difference between the actual output voltage of the battery and the target output voltage, the difference between the actual output voltage of the battery and the target output voltage is always kept less than or equal to the preset threshold. The actual output voltage of the battery is adjusted by the first initial adjustment factor and the second initial adjustment factor, thereby ensuring that the discharge voltage of the battery always conforms to the standard voltage for the current application scenario of the battery. This can reduce the actual voltage consumption of the battery. Therefore, it can achieve the effect of improving the flexibility of battery applications and the usage duration of the battery.

### BRIEF DESCRIPTION OF DRAWINGS

To more clearly illustrate the technical solutions of the embodiments of the present disclosure, the following will briefly introduce the drawings used in the embodiments. It should be understood that the following drawings only show some embodiments of the present disclosure, and therefore they should not be regarded as a limitation on the scope. Those ordinary skilled in the art can also obtain other related drawings based on these drawings without inventive effort.

FIG. 1 is a flowchart of the first method for controlling battery provided in the embodiments of the present disclosure;

FIG. 2 is a flowchart of the second method for controlling battery provided in the embodiments of the present disclosure;

FIG. 3 is a curve chart showing the actual output voltage of a battery varying with adjustment factors provided in the embodiments of the present disclosure;

FIG. 4 is a flowchart of a high-temperature discharge protection method for a battery provided in the embodiments of the present disclosure;

FIG. 5 is a flowchart of a high-temperature charging protection method for a battery provided in the embodiments of the present disclosure;

FIG. 6 is a schematic diagram of the structure of a device for controlling the battery provided in the embodiments of the present disclosure; and

FIG. 7 is a schematic diagram of the structure of a computer apparatus provided by the embodiments of the present disclosure.

### DETAILED DESCRIPTION OF EMBODIMENTS

In order to make the objective, technical solutions, and advantages of the embodiments of the present disclosure clearer, the following description will provide a clear and comprehensive explanation for the technical solutions in the embodiments of the present disclosure with reference to the drawings in the embodiments of the present disclosure. Clearly, the described embodiments are part of the embodiments of the present disclosure and not all of the embodiments. The components of embodiments of the present disclosure which are generally described and illustrated in the drawings herein can be arranged and designed in a variety of different configurations.

Accordingly, the following detailed description of the embodiments of the present disclosure provided in the drawings is not intended to limit the scope of the claimed disclosure but merely represents selected embodiments of the present disclosure. Based on the embodiments in the present disclosure, all other embodiments obtained by those of ordinary skill in the art without making inventive efforts are within the scope of protection of the present disclosure.

Currently, in related technologies, the discharge monitoring for lithium-ion batteries is achieved by regulating the output voltage of lithium-ion batteries using a DC-DC step-down voltage-regulated circuit. Specifically, by using a monitoring and controlling circuit for lithium-ion battery, the output voltage of the lithium-ion battery is monitored. The output feedback depth of the DC-DC step-down voltage-regulated discharge circuit is controlled. When the output voltage of the lithium-ion battery is greater than the low-power voltage V_{L}, the DC-DC step-down voltage-regulated discharge circuit is controlled to lower the output voltage of the lithium-ion battery to the first output voltage for voltage-stabilization output. When the output voltage of the lithium-ion battery is greater than the discharge cutoff voltage V_{D} and equal to or less than the low-power voltage V_{L}, the DC-DC step-down voltage-regulated discharge circuit is controlled to lower the output voltage of the lithium-ion battery to the second output voltage for voltage-stabilization output. Additionally, when the output voltage of the lithium-ion battery after charging is greater than V_{L}+ΔV₁, the DC-DC step-down voltage-regulated discharge circuit is controlled to restore the first output voltage for voltage-stabilization output, where V_{L} represents the set low-power voltage of the lithium-ion battery, ΔV₁ represents the set hysteresis voltage for the detection threshold of the low-power voltage of the lithium-ion battery, and V_{D} represents the set discharge cutoff voltage for the lithium-ion battery. However, when this approach controls the discharge process of the lithium-ion battery, the voltage of the lithium-ion battery when discharging is always a constant voltage, which significantly shortens the usage duration of lithium-ion batteries, and the lithium-ion batteries are less flexible to adapt to various scenarios.

Therefore, the embodiments of the present disclosure provide a method for controlling the battery, by determining the current application scenario of the battery, determining the target output voltage for the battery, obtaining the first initial adjustment factor and the second initial adjustment factor, monitoring the actual output voltage of the battery in real time, and adjusting the first initial adjustment factor and/or the second initial adjustment factor based on the target output voltage and the actual output voltage when the difference between the actual output voltage of the battery and the target output voltage of the battery is greater than a preset threshold, the difference between the actual output voltage of the battery and the target output voltage is made to be less than or equal to the preset threshold. The first initial adjustment factor and the second initial adjustment factor can effectively regulate the actual output voltage of the battery, adjust the variation rate of voltage, and conserve the power of the battery itself. Therefore, it can achieve the effect of improving the flexibility of battery applications and the usage duration of the battery.

The embodiments of the present disclosure are illustrated using the example of the method for controlling the battery applied to lithium-ion batteries. However, this does not mean that the embodiments of the present disclosure are limited to the control of batteries only in lithium-ion batteries.

Below, a detailed explanation of the method for controlling the battery provided in the embodiments of the present disclosure will be provided.

FIG. 1 is a flowchart of the method for controlling the battery provided in the present disclosure, wherein the method can be applied to the processor. Referring to FIG. 1, the embodiments of the present disclosure provide a method for controlling the battery, comprising the following steps.

S101: obtaining a first initial adjustment factor and a second initial adjustment factor based on the current application scenario of the battery, and obtaining a target output voltage of the battery.

Optionally, the current application scenario of the battery is preset by the manufacturer when manufacturing the battery. For example, batteries from the manufacturer are applied for the electric vehicles, the vehicles, or the mobile phones.

Optionally, the target output voltage of the battery can be determined based on the current application scenario of the battery. The target output voltage refers to the standard voltage for the battery in its current application scenario. For example, if a lithium-ion battery is used in an electric vehicle, the target output voltage can be set to 48V, the target output voltage can be set to 60V, or the target output voltage can be set to 72V, depending on the model of the electric vehicle. It is worth noting that one model of an electric vehicle can have more than one possible target output voltages for the corresponding lithium-ion battery. For example, if the standard supply voltage for an electric vehicle is 48V, then the target voltage for the lithium-ion battery of the electric vehicle would also be 48V. However, the standard supply voltage when the electric vehicle starts is 12V, then the target voltage during the startup of the electric vehicle would be 12V, and so on. Based on the current application scenario of the battery, the target output voltage of the battery can change at any time, and the actual output voltage of the battery will also vary accordingly.

Optionally, both the first initial adjustment factor and the second initial adjustment factor are pre-stored in the processor. The first initial adjustment factor has a value range between −3.0 and 6.0, and the second initial adjustment factor has a value range between 0.1 and 1.4. Both the first initial adjustment factor and the second initial adjustment factor are used to adjust the output voltage of the lithium-ion battery. The first initial adjustment factor and the second initial adjustment factor function together.

S102: monitoring an actual output voltage of the battery in real time.

Optionally, a battery control circuit arranged within the battery can monitor the voltage of the battery in real time. When the battery is in a discharging state, the battery voltage monitored in real time is the actual output voltage of the battery. The actual output voltage of the battery has real-time characteristics, and the actual output voltage of the battery changes over time.

S103: adjusting, if the difference between the actual output voltage and the target output voltage is greater than a preset threshold, the first initial adjustment factor and/or the second initial adjustment factor based on the target output voltage and the actual output voltage, so as to make the difference between the actual output voltage and the target output voltage less than or equal to the preset threshold.

Optionally, when the difference between the actual output voltage of the battery and the target output voltage is greater than a preset threshold, the actual output voltage of the battery is outside the standard output voltage range for the current application scenario of the battery. It is worth noting that the difference between the actual output voltage of the battery and the target output voltage can be either positive or negative. The actual output voltage of the battery can be greater than or less than the target output voltage.

Optionally, the first initial adjustment factor and the second initial adjustment factor can be adjusted based on the difference between the actual output voltage of the battery and the target output voltage, which ensures that the actual output voltage of the battery, after being processed by the first initial adjustment factor and the second initial adjustment factor, falls within the standard output voltage range for the current application scenario of the battery. The first initial adjustment factor and the second initial adjustment factor can be adjusted simultaneously, or only one of them is adjusted.

It is important to note that the preset threshold is used to indicate the range of the difference between the actual output voltage of the battery and the target output voltage, that is to say, the actual output voltage of the battery must fall within this range to ensure that the battery functions properly in the current application scenario. The preset threshold can be 0V, 3V, 5V, etc. The present disclosure uses a preset threshold of 0V as an example, but the preset threshold is not limited to the value of 0V. The present disclosure does not restrict the range of values for the preset threshold.

In the embodiments of the present disclosure, by determining the current application scenario of the battery, determining the corresponding target output voltage for the battery, obtaining the first initial adjustment factor and the second initial adjustment factor stored in the processor, obtaining the actual output voltage of the battery in real time, and adjusting the first initial adjustment factor and/or the second initial adjustment factor in real time based on the difference between the actual output voltage of the battery and the target output voltage, the difference between the actual output voltage of the battery and the target output voltage is always kept less than or equal to the preset threshold, and thus the actual voltage consumption of the battery can be reduced. Therefore, it can achieve the effect of improving the flexibility of battery applications and the usage duration of the battery.

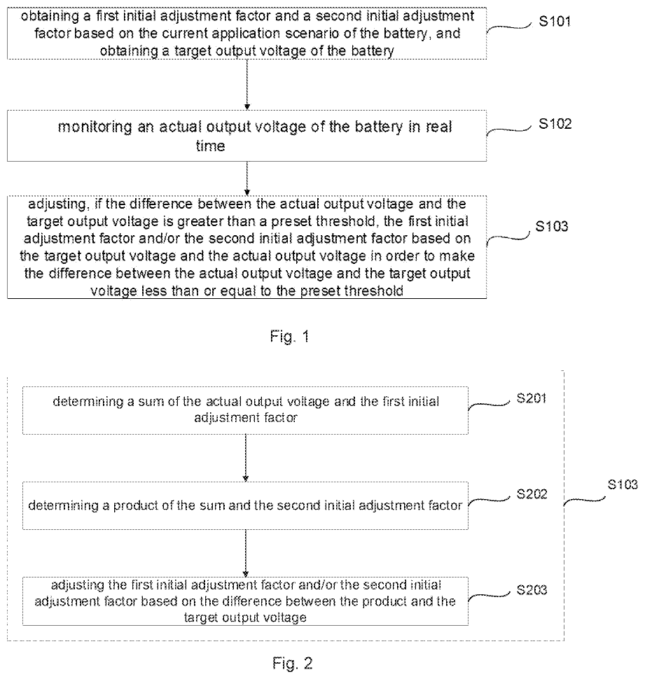

In one possible implementation, referring to FIG. 2, the operations of step S103 can be detailed in the following steps.

S201: determining a sum of the actual output voltage and the first initial adjustment factor.

Optionally, the addition of the actual output voltage of the battery with the first initial adjustment factor can achieve both voltage boost and voltage reduction for the actual output voltage of the battery.

S202: determining a product of the sum and the second initial adjustment factor.

Optionally, determining the product of the sum and the second initial adjustment factor allows for controlling the rate of change in the output voltage of the battery according to voltage variation requirements, which further adjusts the discharge voltage of the battery.

S203: adjusting the first initial adjustment factor and/or the second initial adjustment factor based on the difference between the product and the target output voltage.

Optionally, based on the difference between the product and the target output voltage, the first initial adjustment factor and/or the second initial adjustment factor can be adjusted to ensure that the difference between the actual output voltage of the battery and the target output voltage of the battery consistently remains equal to or less than the preset threshold.

Optionally, the first initial adjustment factor and/or the second initial adjustment factor can be adjusted using the following formula (1). Specifically, the adjustment for the first initial adjustment factor and/or the second initial adjustment factor can be performed separately based on the difference between each actual output voltage of the battery and the target output voltage by applying the following formula (1).

$${V}_{O U T} = ( {V}_{B A T} + {V}_{R E G} ) * {V}_{F} , \qquad ( 1 )$$

where V_{OUT} represents the target output voltage of the battery, V_{BAT} represents the actual output voltage of the battery, V_{REG} represents the first initial adjustment factor, and V_{F} represents the second initial adjustment factor. Both the first initial adjustment factor and the second initial adjustment factor are used to adjust the actual output voltage of the battery.

Optionally, V_{OUT} is obtained from the standard voltage for discharging the battery corresponding to the current application scenario of the battery. V_{BAT} is obtained from the actual output voltage of the battery monitored in real time by the battery control circuit and has a certain timeliness. V_{REG} and V_{F} are adjusted based on the actual output voltage and the target output voltage of the battery.

As an example, it is preset that battery A, manufactured by the factory, is intended for use in electric vehicle a. The standard voltage for electric vehicle a is 48V, and the preset threshold is 0. If electric vehicle a is currently in the startup phase, where the standard voltage for the startup of electric vehicle a is 12V, and the control circuit simultaneously monitors that the actual output voltage of battery A is 10V, due to the actual output voltage of battery A being below the target output voltage of the battery, the first initial adjustment factor and/or the second initial adjustment factor need to be adjusted, in order not to affect the normal startup of the electric vehicle a. In this scenario, the difference between the actual output voltage of battery A and the target output voltage is −2V, indicating that battery A requires a voltage boost. Considering the current application scenario, the processor adjusts the value of the first initial adjustment factor to 2. The sum of the actual output voltage of the battery A and the first initial adjustment factor is 12V. At this point, the second initial adjustment factor can be set to 1. If a quick startup is required currently, it is required to increase the change frequency of voltage, then the second initial adjustment factor is adjusted to 1.2. According to the computational relationship, the processor then adjusts the first initial adjustment factor to 0.

In the embodiments of the present disclosure, by preliminarily determining the difference between the actual output voltage of the battery and the target output voltage corresponding to the current application scenario of the battery, determining the first initial adjustment factor, adding the first initial adjustment factor to the actual output voltage of the battery, multiplying the result of the addition to the current second initial adjustment factor, and further adjusting the first initial adjustment factor and/or the second initial adjustment factor based on the difference between the multiplication result and the target output voltage, the difference between the actual output voltage of the battery and the target output voltage is less than the preset threshold. In this way, the output voltage of the battery can consistently meet the requirements of various application scenarios, thereby reducing the actual voltage consumption of the battery. Therefore, it can achieve the effect of improving the flexibility of battery applications.

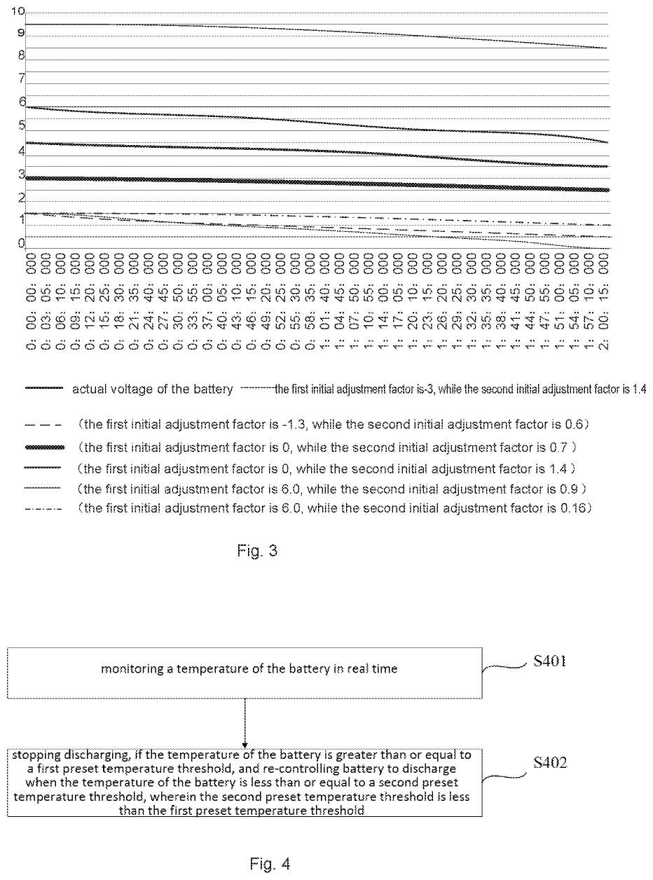

FIG. 3 is a curve chart showing the actual output voltage of a battery varying with adjustment factors provided in the embodiments of the present disclosure. As shown in FIG. 3, under the same target output voltage, different first initial adjustment factors and/or second initial adjustment factors can alter the change curve of the actual output voltage of the battery.

FIG. 4 is a flowchart of a high-temperature discharge protection method for a battery provided in the embodiments of the present disclosure. As shown in FIG. 4, the method for controlling the battery also comprises high-temperature discharge protection. The method for controlling the battery provided in the present disclosure further comprises the following steps.

S401: monitoring a temperature of the battery in real time.

Optionally, the temperature of the battery is monitored in real time by the battery control circuit provided in the battery.

S402: stopping discharging, if the temperature of the battery is greater than or equal to a first preset temperature threshold, and re-controlling battery to discharge when the temperature of the battery is less than or equal to a second preset temperature threshold, wherein the second preset temperature threshold is less than the first preset temperature threshold.

Optionally, if the battery is in a discharging state, and the battery control circuit monitors that the current temperature of the battery is greater than or equal to the first preset temperature threshold, the battery will stop discharging. The first preset temperature threshold serves as the high-temperature limit for battery discharge. In general, lithium-ion batteries have high-temperature limits in the range of 40-60 degrees Celsius. Once exceeding the first preset temperature threshold, the battery can lead to accidents such as fire or explosion. The first preset temperature threshold can be set at 35 degrees Celsius, 40 degrees Celsius, 45 degrees Celsius, etc. The present disclosure does not specifically limit it.

Optionally, after the battery stops discharging, it will only re-control the battery to discharge when the battery control circuit monitors that the current temperature of the battery is less than or equal to the second preset temperature threshold. The second temperature threshold represents the safe temperature value for the battery in normal operation. In general, the normal operating temperature range for lithium-ion batteries is 0-40 degrees Celsius, with the optimal operating temperature range around 20 degrees Celsius. The second temperature threshold can be set at 18 degrees Celsius, 20 degrees Celsius, 25 degrees Celsius, etc. The present disclosure does not specifically limit it.

It is worth noting that the second preset temperature threshold is lower than the first preset temperature threshold. The first preset temperature threshold is used to indicate the high-temperature limit for battery operation, while the second preset temperature threshold is used to indicate the safe operating temperature for the battery.

In one possible implementation, the method for controlling the battery provided in the present disclosure also comprises a battery discharge cutoff. The battery discharge cutoff controlling method comprises:
stopping discharging, if the actual output voltage of the battery is less than or equal to the preset discharge cutoff voltage.

Optionally, if the battery control circuit monitors that the actual output voltage of the battery is less than or equal to the preset discharge cutoff voltage, it controls the battery to stop discharging. The preset discharge cutoff voltage is used to indicate the minimum limit of the discharge of the battery. The discharge cutoff voltage of the battery is generally 10% of the standard voltage of the battery. For example, the discharge cutoff voltage for a 48V lithium-ion battery is 4.8V, and the preset discharge cutoff voltage of the battery is determined based on the capacity of the battery.

Optionally, when the actual output voltage of the battery reaches the preset discharge cutoff voltage, the discharging is stopped, which can effectively prevent the battery from over-discharging and prolong its lifespan. This helps protect the battery, improve its reliability, and ensure its lifespan.

FIG. 5 is a flowchart of a high-temperature charging protection method for a battery provided in the embodiments of the present disclosure. As shown in FIG. 5, the method for controlling the battery also comprises high-temperature charging protection. The method for controlling the battery provided in the present disclosure further comprises the following steps.

S501: monitoring a temperature of the battery in real time.

Optionally, the control circuit of the battery monitors the temperature of the battery in real time during charging of the battery.

S502: charging the battery first in trickle charging mode if the temperature of the battery is less than or equal to a third preset temperature threshold, then charging the battery in normal charging mode when the temperature of the battery is greater than or equal to a fourth preset temperature threshold, wherein the fourth preset temperature threshold is greater than the third preset temperature threshold.

Optionally, if the control circuit of the battery monitors that the temperature of the battery is currently lower than or equal to the third preset temperature threshold during the charging state of the battery, the battery is firstly charged in trickle charging mode. The third preset temperature threshold is the lowest temperature limit for battery charging. When it is below the third preset temperature threshold, the battery cannot be charged normally. The low-temperature limit for lithium-ion batteries is −5 to 0 degrees Celsius. The third preset temperature threshold can be set to 0 degrees Celsius, 5 degrees Celsius, etc. The present disclosure does not specifically limit it.

Optionally, when the real-time temperature of the battery is lower than the third temperature threshold, the battery may face the phenomenon of not being able to be charged. Low-temperature environments can have a significant impact on the internal resistance of the battery, which reduces its performance and usage duration. When the temperature of the battery is monitored to be lower than the third preset temperature threshold, it is firstly charged in trickle charging mode. This can serve to preheat the battery, and trickle charging mode can compensate for the capacity loss caused by the battery in a low-temperature state, thereby keeping the battery in a nearly fully charged state with a continuous small current charging mode.

Optionally, when the temperature of the battery in trickle charging mode reaches or exceeds the fourth preset temperature threshold, the charging mode of the battery switches from trickle charging mode to normal charging mode. The fourth preset temperature threshold represents the safe charging temperature for the battery, wherein the safe charging temperature for lithium-ion batteries typically ranges from 5-35 degrees Celsius. The fourth preset temperature threshold can be 5 degrees Celsius, 10 degrees Celsius, etc. The present disclosure does not limit it.

It is worth noting that the fourth preset temperature threshold is greater than the third preset temperature threshold. The fourth preset temperature threshold is used to indicate the temperature for normal charging of the battery, while the third preset temperature threshold indicates the lowest temperature limit for battery charging.

In one possible implementation, the method for controlling the battery provided in the present disclosure also comprises high-temperature charging protection for the battery, wherein the method for controlling the battery further comprises:

stopping charging if the temperature of the battery is greater than or equal to a fifth preset temperature threshold, and recharging when the temperature of the battery is less than or equal to a sixth preset temperature threshold, wherein the sixth preset temperature threshold is less than the fifth preset temperature threshold.

If the battery control circuit monitors that the temperature of the battery is equal to or greater than the fifth preset temperature threshold while the battery is in a charging state, charging will be stopped. During the charging process of the battery, the temperature of the battery will continue to rise, and if charging is continued after the temperature of the battery reaches the fifth preset temperature threshold, it may lead to battery explosion or fire. The fifth preset temperature threshold represents the maximum temperature limit during the charging process of the battery, with the highest temperature during lithium-ion battery charging ranging from 45-60 degrees Celsius. The fifth preset temperature threshold can be set to 45 degrees Celsius, 40 degrees Celsius, etc., without specific limitations in the present disclosure.

Optionally, when the battery temperature reaches the fifth preset temperature threshold, the charging is stopped, and until the control circuit of the battery monitors that the temperature of the battery is equal to or lower than the sixth preset temperature threshold, the charging for the battery is re-started. The sixth preset temperature threshold represents the safe charging temperature for the battery charging, wherein the safe charging temperature typically ranges from 15 to 35 degrees Celsius for lithium-ion batteries. The sixth preset temperature threshold can be 15 degrees Celsius, 20 degrees Celsius, 30 degrees Celsius, etc., without specific limitations in the present disclosure.

It is worth noting that the sixth preset temperature threshold is less than the fifth preset temperature threshold. The sixth preset temperature threshold is used to indicate the safe charging temperature of the battery, while the fifth preset temperature threshold indicates the maximum temperature limit for battery charging.

In one possible implementation, the method for controlling the battery provided in the present disclosure also comprises normal-temperature charging protection for the battery, wherein the method for controlling the battery further comprises:

charging the battery first in trickle charging mode if the actual output voltage of the battery is less than or equal to a first preset voltage, and charging the battery in constant-voltage and constant-current mode when the actual output voltage of the battery is greater than a second preset voltage.

Optionally, if the control circuit of the battery monitors that the current battery temperature is within the normal operating range of the battery and the actual output voltage of the battery is less than or equal to the first preset voltage, then the battery is charged first in trickle charging mode. If the actual output voltage of the battery is less than or equal to the first preset voltage, it indicates that the battery has lost power, and the first preset voltage can be 0V, 3V, etc. The present disclosure does not limit it.

It is worth noting that when the actual output voltage of the battery is less than the first preset voltage, charging the battery first in trickle charging mode can compensate for the loss caused by the over-discharge of the battery and restore the capacity of the battery.

Optionally, when the battery is charged in trickle charging mode and its actual output voltage exceeds the second preset voltage, the battery is charged in normal charging mode with constant voltage and constant current. The second preset voltage refers to the voltage at which the capacity compensation of the battery is completed. For example, if a 48V battery has a second preset voltage of 12V, and the second preset voltage can be 10V, 12V, etc. The present disclosure does not limit it. It is worth noting that the second preset voltage is higher than the first preset voltage, and the second preset voltage indicates that the battery is in a state without power loss, while the first preset voltage indicates that the battery is in a power-loss state.

The following describes the device, apparatus, and computer-readable storage medium used to implement the method for controlling the battery provided in the present disclosure. The specific implementation process and technical effects can be found in the above description, and will not be reiterated hereafter.

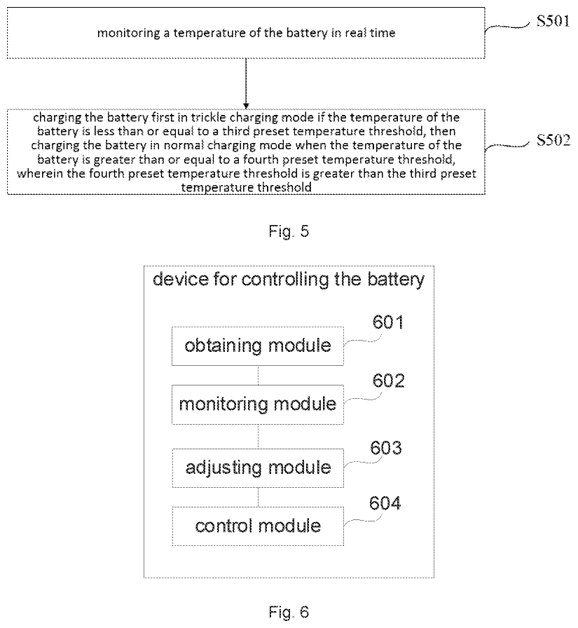

FIG. 6 is a schematic diagram of the structure of a device for controlling the battery provided in the embodiments of the present disclosure. Referring to FIG. 6, the device comprises:

an obtaining module 601, configured for obtaining a first initial adjustment factor and a second initial adjustment factor based on the current application scenario of the battery, and obtaining a target output voltage of the battery;
a monitoring module 602, configured for monitoring an actual output voltage of the battery in real time; and
an adjusting module 603, configured for adjusting, if the difference between the actual output voltage and the target output voltage is greater than a preset threshold, the first initial adjustment factor and/or the second initial adjustment factor based on the target output voltage and the actual output voltage, so as to make the difference between the actual output voltage and the target output voltage less than or equal to the preset threshold.

In one possible implementation, the adjusting module 603 is specifically configured for
determining a sum of the actual output voltage and the first initial adjustment factor;
determining a product of the sum and the second initial adjustment factor; and
adjusting the first initial adjustment factor and/or the second initial adjustment factor based on the difference between the product and the target output voltage.

In one possible embodiment, the device for controlling the battery further comprises:
a monitoring module 602, configured for monitoring the temperature of the battery in real time; and
a control module 604, configured to stop discharging if the temperature of the battery is greater than or equal to a first preset temperature threshold, and re-control the battery to discharge when the temperature of the battery is less than or equal to a second preset temperature threshold, wherein the second preset temperature threshold is less than the first preset temperature threshold.

In one possible implementation, the control module 604 is further configured for
stopping discharging if the actual output voltage of the battery is less than or equal to the preset discharge cutoff voltage.

In one possible embodiment, the device for controlling the battery further comprises:
a monitoring module 602, configured for monitoring the temperature of the battery in real time; and
a control module 604, further configured for charging the battery first in trickle charging mode if the temperature of the battery is less than or equal to a third preset temperature threshold, and then charging the battery in normal charging mode when the temperature of the battery is greater than or equal to a fourth preset temperature threshold, wherein the fourth preset temperature threshold is greater than the third preset temperature threshold.

In one possible implementation, the control module 604 is specifically configured to
stop charging if the temperature of the battery is greater than or equal to a fifth preset temperature threshold, and recharge the battery when the temperature of the battery is less than or equal to a sixth preset temperature threshold, wherein the sixth preset temperature threshold is less than the fifth preset temperature threshold.

In one possible implementation, the control module 604 is further specifically configured to
charge the battery first in trickle charging mode if the actual output voltage of the battery is less than or equal to a first preset voltage, and charge the battery in constant-voltage and constant-current mode when the actual output voltage of the battery is greater than a second preset voltage.

The above-mentioned device is used to execute the method provided in the previous embodiments. Its implementation principles and technical effects are similar and will not be reiterated here.

The above-mentioned modules can be configured as one or more integrated circuits to implement the above method, for example, one or more application specific integrated circuits (ASIC), one or more microprocessors, or one or more field programmable gate arrays (FPGA), among others. For another example, when one of the aforementioned modules is implemented in the form of processing element calling program code, the processing element can be a general-purpose processor, such as a central processing unit (short for CPU), or other processors capable of calling program code. Furthermore, these modules can be integrated together and implemented in the form of a system-on-a-chip (short for SOC).

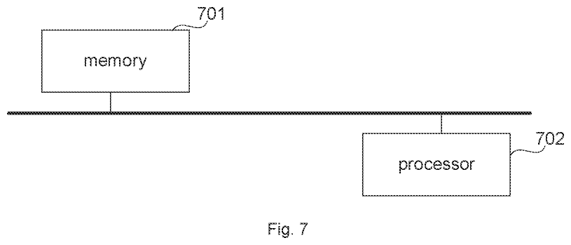

FIG. 7 is a schematic diagram of the structure of a computer apparatus provided by the embodiments of the present disclosure. Referring to FIG. 7, a computer apparatus comprises a memory 701 and a processor 702. The memory 701 stores computer programs that can run on the processor 702. When the processor 702 executes the computer programs, it carries out the steps from any of the method embodiments described above.

The embodiments of the present disclosure also provide a computer-readable storage medium, wherein the computer-readable storage medium stores computer programs. When these computer programs are executed by a processor, they enable the implementation of the steps from any of the method embodiments described above.

Optionally, the present disclosure also provides a program product, such as a computer-readable storage medium, comprising a program, wherein when executed by a processor, the program is used to perform any of the embodiments of the method for controlling the battery described above.

In the several embodiments provided in the present disclosure, it should be understood that the devices and methods disclosed can be implemented in other ways. For example, the above-described embodiments of the device are merely schematic. For example, the division of the units, which is only a logical functional division, can be divided in another way when actually implemented; also, for example, multiple units or components can be combined or can be integrated into another system, or some features can be ignored, or not implemented. On another point, the mutual coupling, direct coupling, or communication connection shown or discussed herein can be an indirect coupling or communication connection through some interfaces, devices, or units, which can be electrical, mechanical, or other forms.

The units illustrated as separate components can/cannot be physically separated, and the components displayed as units can/cannot be physical units, i.e., they can be located in one place or distributed to a plurality of network units. Some or all of these units can be selected according to actual needs to achieve the objective of the embodiment solution.

Further, each functional unit in each embodiment of present disclosure can be integrated into a single processing unit, each unit can be physically present separately, or two or more units can be integrated into a single unit. The integrated units mentioned above can be implemented both in the form of hardware and in the form of hardware combined with software functional units.

The above integrated units implemented in the form of software functional units can be stored on a computer-readable storage medium. The above software functional units, stored on a storage medium, comprise various instructions that enable a computer apparatus (such as a personal computer, server, or network device) or processor to execute certain steps of the methods provided in various embodiments of the present disclosure. The aforementioned storage media comprises various media that can store program code, such as USB drives, external hard drives, read-only memory (ROM), random access memory (RAM), magnetic disks, or optical discs, among others.

The above is only a specific embodiment of the present disclosure, but the scope of protection of the present disclosure is not limited thereto. Any person skilled in the art can easily envisage changes or substitutions within the technical scope disclosed in the present disclosure, which should be encompassed within the scope of protection of the present disclosure. Therefore, the scope of protection of the present disclosure shall be based on the scope of protection of the claims.

The above is only a preferred embodiment of the present disclosure, which is not intended to limit it, and the present disclosure may have various changes and variations for those skilled in the art. Any modification, equivalent substitution, improvement, etc. made within the spirit and principles of the present disclosure shall be included in the scope of protection of the present disclosure.

1. A method for controlling a battery, comprising:
obtaining a first initial adjustment factor and a second initial adjustment factor based on a current application scenario of the battery, and obtaining a target output voltage of the battery;
monitoring an actual output voltage of the battery in real time; and
adjusting, when a difference between the actual output voltage and the target output voltage is greater than a preset threshold, the first initial adjustment factor and/or the second initial adjustment factor based on the target output voltage and the actual output voltage, so as to make a difference between the actual output voltage and the target output voltage less than or equal to the preset threshold.

2. The method for controlling the battery according to claim 1, wherein the step of adjusting the first initial adjustment factor and/or the second initial adjustment factor based on the target output voltage and the actual output voltage comprises:
determining a sum of the actual output voltage and the first initial adjustment factor;
determining a product of the sum and the second initial adjustment factor; and
adjusting the first initial adjustment factor and/or the second initial adjustment factor based on a difference between the product and the target output voltage.

3. The method for controlling the battery according to claim 1, wherein the method further comprises:
monitoring a temperature of the battery in real time; and
stopping discharging when a temperature of the battery is greater than or equal to a first preset temperature threshold, and re-controlling the battery to discharge when a temperature of the battery is less than or equal to a second preset temperature threshold, wherein the second preset temperature threshold is less than the first preset temperature threshold.

4. The method for controlling the battery according to claim 1, wherein the method further comprises:
stopping discharging when the actual output voltage of the battery is less than or equal to a preset discharge cutoff voltage.

5. The method for controlling the battery according to claim 1, wherein the method further comprises:
monitoring a temperature of the battery in real time; and
charging the battery first in a trickle charging mode when a temperature of the battery is less than or equal to a third preset temperature threshold, and then charging the battery in a normal charging mode when a temperature of the battery is greater than or equal to a fourth preset temperature threshold, wherein the fourth preset temperature threshold is greater than the third preset temperature threshold.

6. The method for controlling the battery according to claim 5, wherein the method further comprises:
stopping charging when a temperature of the battery is greater than or equal to a fifth preset temperature threshold, and recharging when a temperature of the battery is less than or equal to a sixth preset temperature threshold, wherein the sixth preset temperature threshold is less than the fifth preset temperature threshold.

7. The method for controlling the battery according to claim 1, wherein the method further comprises:
charging the battery first in a trickle charging mode when the actual output voltage of the battery is less than or equal to a first preset voltage, and charging the battery in a constant-voltage and constant-current mode when the actual output voltage of the battery is greater than a second preset voltage.

8. A computer apparatus, comprising a memory, and a processor, wherein the memory stores a computer program that can be executed on the processor, and when the processor executes the computer program, the steps of the method according to claim 1 are implemented.

9. A computer-readable storage medium, wherein the computer-readable storage medium stores a computer program, and when the computer program is executed by a processor, the steps of the method according to claim 1 are implemented.
